(19) United States
(12) Patent Application Publication
(10) Pub. No.: US 2023/0130356 A1
(43) Pub. Date: Apr. 27, 2023

(54) PACKAGE SUBSTRATE AND SEMICONDUCTOR PACKAGE INCLUDING THE SAME

(71) Applicant: Samsung Electronics Co., Ltd., Suwon-si (KR)

(72) Inventor: Jongbeom PARK, Seoul (KR)

(73) Assignee: Samsung Electronics Co., Ltd., Suwon-si (KR)

(21) Appl. No.: 17/734,424

(22) Filed: May 2, 2022

(30) Foreign Application Priority Data
Oct. 27, 2021 (KR) 10-2021-0144371

(51) Int. Cl. H01L 23/498

(52) U.S. Cl. CPC H01L 23/49838; H01L 23/49816; H01L 23/49822; H01L 2924/3511; H01L 2924/3512; H01L 24/16

(57) ABSTRACT

A package substrate may include an insulation substrate, a plurality of upper pads, a plurality of first lower pads, a plurality of second lower pads and a plurality of patches. The insulation substrate may have a lower surface including a first region where external terminals may be mounted and a second region where an electronic component may be mounted. The first lower pads may be arranged in the first region. The second lower pads may be arranged in the second region. The patches may be arranged between the second lower pads in the second region to suppress a warpage of the electronic component. Thus, the warpage may not be generated at the electronic component to prevent a crack from being generated in the electronic component.

### CROSS-RELATED APPLICATION

This application claims priority under 35 USC § 119 to Korean Patent Application No. 10-2021-0144371, filed on Oct. 27, 2021 in the Korean Intellectual Property Office (KIPO), the contents of which are herein incorporated by reference in their entirety.

### BACKGROUND

### 1. Field

Example embodiments relate to a package substrate and a semiconductor package including the same. More particularly, example embodiments relate to a semiconductor substrate used for packaging a semiconductor chip and a semiconductor package including the package substrate.

### 2. Description of the Related Art

Generally, a package substrate used, e.g., for packaging a semiconductor chip, may include a plurality of upper pads and a plurality of lower pads. External terminals may be mounted on the lower pads. Additionally, an electric component (e.g., a passive element, such as a capacitor) may be mounted on the lower pads.

According to related arts, the electric component may be mounted on the lower pad using a nozzle. During the mounting process, a warpage may be generated at the electric component due to a load from the nozzle. The warpage may cause a crack of the electric component.

### SUMMARY

Example embodiments provide a package substrate that may be capable of preventing a warpage of an element.

Example embodiments also provide a semiconductor package including the above-mentioned package substrate.

According to some example embodiments, there may be provided a package substrate. The package substrate may include an insulation substrate including a first region and a second region on a lower surface of the insulating substrate; a plurality of upper pads on an upper surface of the insulation substrate; a plurality of first lower pads in the first region, the plurality of first lower pads configured to mount external terminals; a plurality of second lower pads in the second region, the plurality of second lower pads configured to mount an electronic component; a plurality of patches between the second lower pads in the second region, the plurality of patches configured to suppress warpage of the electronic component; and at least one dam extending along an edge portion of the second region, the at least one dam configured to auxiliarily suppress warpage of the electronic component. Each of the patches may have a diameter of 50 μm to 70 μm and a thickness of 35 μm to 38 μm.

According to some example embodiments, there may be provided a package substrate. The package substrate may include an insulation substrate including a first region and a second region on a lower surface of the insulation substrate; a plurality of upper pads on an upper surface of the insulation substrate; a plurality of first lower pads in the first region, the plurality of first lower pads configured to mount external terminals; a plurality of second lower pads arranged in the second region, the plurality of second lower pads configured to mount an electronic component; and a plurality of patches between the second lower pads in the second region, the plurality of patches configured to suppress warpage of the electronic component.

According to some example embodiments, there may be provided a semiconductor package. The semiconductor package may include a package substrate including an insulation substrate including a first region and a second region on a lower surface of the insulation substrate, a plurality of upper pads on an upper surface of the insulation substrate, a plurality of first lower pads in the first region, a plurality of second lower pads in the second region, and a plurality of patches between the second lower pads in the second region and configured to suppress warpage of an electronic component; a semiconductor chip mounted on the upper pads; a plurality of external terminals mounted on the first lower pads; and the electronic component mounted on the second lower pads.

According to some example embodiments, the patches may be arranged between the second lower pads in the second region of the lower surface of the package substrate to prevent the warpage of the electronic component on the second lower pads from being generated. Further, the dam may be arranged on the edge portions of the second region to auxiliarily suppress the warpage of the electronic component. As a result, the generation of cracks may be prevented and/or mitigated in the electronic component.

### BRIEF DESCRIPTION OF THE DRAWINGS

Example embodiments will be more clearly understood from the following detailed description taken in conjunction with the accompanying drawings. FIGS. 1 to 11 represent non-limiting, example embodiments as described herein.

FIG. 1 is a bottom view illustrating a package substrate in accordance with some example embodiments;

FIG. 2 is a cross-sectional view illustrating the package substrate in FIG. 1;

FIG. 3 is an enlarged bottom view of a portion “R2” in FIG. 1 corresponding to a second region of the package substrate;

FIG. 4 is an enlarged perspective view illustrating the second region of the package substrate in FIG. 3;

FIG. 5 is a cross-sectional view illustrating the second region of the package substrate in FIG. 4;

FIG. 6 is a perspective view illustrating a package substrate in accordance with some example embodiments;

FIG. 7 is a perspective view illustrating a package substrate in accordance with some example embodiments;

FIG. 8 is a perspective view illustrating a package substrate in accordance with some example embodiments;

FIG. 9 is a perspective view illustrating a package substrate in accordance with some example embodiments;

FIG. 10 is a cross-sectional view illustrating a semiconductor package including the package substrate in FIG. 2; and

FIG. 11 is an enlarged cross-sectional view illustrating an electronic component mounted on a lower surface of the package substrate in FIG. 10.

### DETAILED DESCRIPTION OF THE EMBODIMENTS

Hereinafter, example embodiments will be explained in detail with reference to the accompanying drawings. Example embodiments, however, may be embodied in various different forms, and should not be construed as being limited to only the illustrated embodiments. Rather, the illustrated embodiments are provided as examples so that this disclosure will be thorough and complete, and will fully convey the concepts of this disclosure to those skilled in the art. Accordingly, known processes, elements, and techniques, may not be described with respect to some example embodiments. Unless otherwise noted, like reference characters denote like elements throughout the attached drawings and written description, and thus descriptions will not be repeated.

Spatially relative terms, such as “lower,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, the device may be otherwise oriented (rotated 90 degrees or at other orientations) and the spatially relative descriptors used herein interpreted accordingly.

Although the numerical indicators such as “first,” “second,” “third,” etc., may be used herein to describe various elements, components, regions, layers, and/or sections, these indicators are only used to distinguish one element, component, region, layer, or section, from another region, layer, or section. These elements, components, regions, layers, and/or sections, should not be otherwise limited by these terms, and, for example, a first element, component, region, layer, or section, discussed below may be alternatively termed a second element, component, region, layer, or section, without departing from the scope of this disclosure.

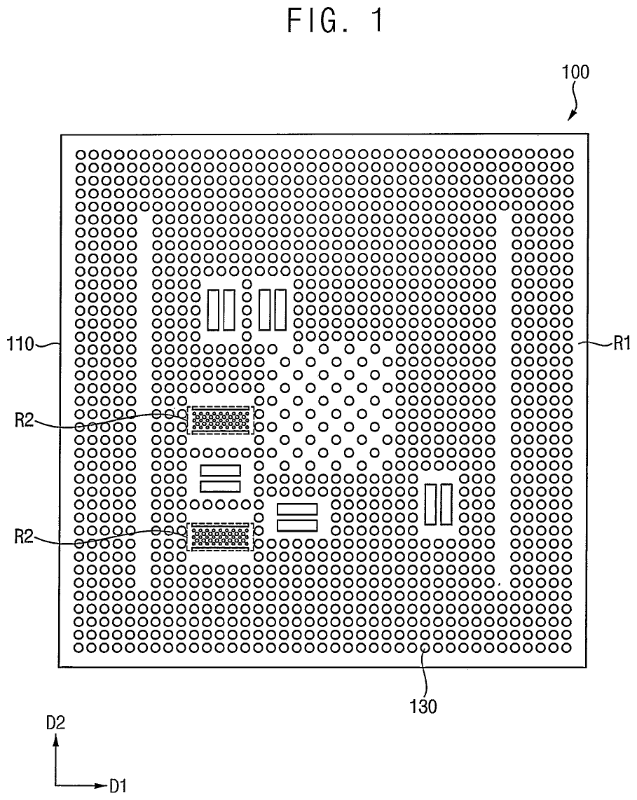

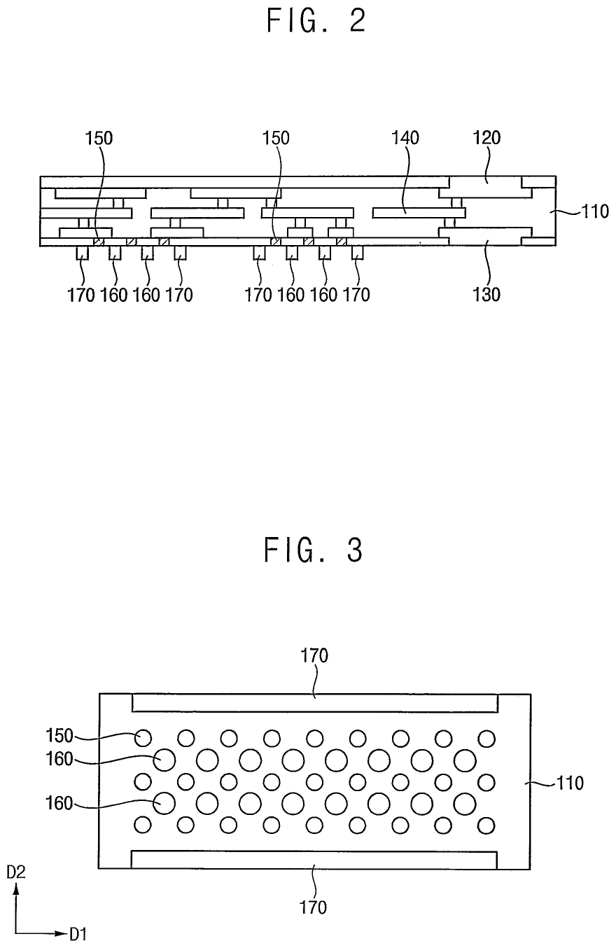

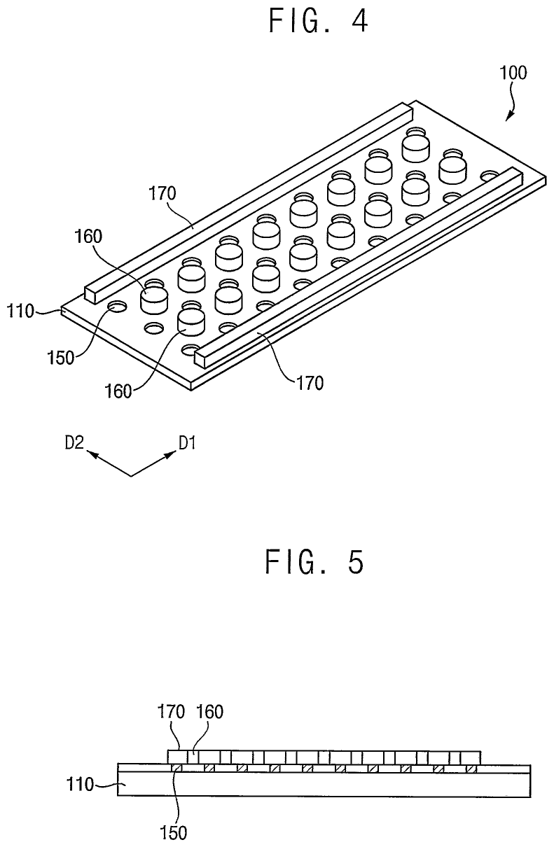

FIG. 1 is a bottom view illustrating a package substrate in accordance with some example embodiments, FIG. 2 is a cross-sectional view illustrating the package substrate in FIG. 1, FIG. 3 is an enlarged bottom view of a portion “R2” in FIG. 1 corresponding to a second region of the package substrate, FIG. 4 is an enlarged perspective view illustrating the second region of the package substrate in FIG. 3 and FIG. 5 is a cross-sectional view illustrating the second region of the package substrate in FIG. 4.

Referring to FIGS. 1 to 5, a package substrate 100 may include an insulation substrate 110, a plurality of upper pads 120, a plurality of first lower pads 130, a plurality of second lower pads 150, a conductive pattern 140, a plurality of patches 160 and a first dam 170.

The insulation substrate 110 may have an upper surface and a lower surface. A first region R1 and a second region R2 may be defined on the lower surface of the insulation substrate 110. External terminals such as solder balls may be mounted on the first region R1. An electronic component such as a passive element may be mounted on the second region R2. In example embodiments, insulation substrate 110 may include two second regions R2 on the lower surface of the insulation substrate 110, but the example embodiments are not limited thereto. For example, the insulation substrate 100 may include one and/or at least three of the second regions R2. The insulation substrate 110 may include an insulation material.

The upper pads 120 may be arranged on the upper surface of the insulation substrate 110. The first and second lower pads 130 and 150 may be arranged on the lower surface of the insulation substrate 110. The conductive pattern 140 may be arranged in the insulation substrate 110. The upper pads 120 may be electrically connected with the first and second lower pads 130 and 150 via the conductive pattern 140. The conductive pattern 140 may include, for example, a wiring pattern and vias electrically connecting the wiring pattern to the upper pads 120 and the first and second lower pads 130 and 150. The upper pads 120, the first and second lower pads 130 and 150, and the conductive pattern 140 may include a conductive material and/or conductive materials. For example, the conductive materials included in the upper pads 120, the first and second lower pads 130 and 150, and the conductive pattern 140 may be the same and/or different conductive materials.

The first lower pads 130 may be arranged in the first region R1. The external terminals may be mounted on the first lower pads 130. The first lower pads 130 may be arranged in the first region R1 along a first direction D1 and a second direction D2 substantially perpendicular to the first direction D1. For example, the first lower pads 130 may be arranged in an array. The first lower pads 130 may be spaced apart from each other by a uniform gap along the first direction D1 and the second direction D2. For example, gaps between the first lower pads 130 may be same. Alternatively, the gaps between the first lower pads 130 may be different from each other. The first lower pads 130 may be configured, for example, to be mounted on an external connection and/or an external device (not illustrated) through the external connection. For example, the gaps between the first lower pads 130 may correspond to the spacing between chip connections and/or fan-out (and/or fan-in) connections as set by a local, internal, and/or international standard (e.g., the World Semiconductor Standards Association and/or the like).

The second lower pads 150 may be arranged in the second region R2. The electronic component may be mounted on the second lower pads 150. The second lower pads 150 may be arranged in the second region R2 along the first direction D1 and the second direction D2. The second lower pads 150 may be spaced apart from each other by a uniform gap along the first direction D1 and the second direction D2. For example, gaps between the second lower pads 150 may be same. Alternatively, the gaps between the second lower pads 150 may be different from each other. The second lower pads 150 may be configured, for example, to be mounted to an electronic component. For example, the gap between the second lower pads 150 may correspond to the spacing between the connections of the electronic component. In some example embodiments, the gaps between (and/or the diameter of) the first lower pads 130 may be, for example, greater than the gaps between (and/or the diameter of) the second lower pads 150.

During the mounting of the electronic component (and/or components) on the second lower pads 150 using a nozzle, a warpage may be generated at the electronic component by a load applied from the nozzle to the electronic component. In order to prevent the generation of the warpage at the electronic component, the patches 160 and the first dam 170 may be arranged in the second region R2.

The patches 160 may be arranged between the second lower pads 150 in the second region R2. For example, the patches 160 may also be arranged along the first direction D1 and the second direction D2. Thus, gaps between the patches 160 may be same. Alternatively, the gaps between the patches 160 may be different from each other. The patches 160 may be configured to support the electronic component on the second lower pads 150. Thus, each of the patches 160 may have an upper surface configured to contact a central portion of a lower surface of the electronic component. Therefore, the patches 160 may upwardly support the central portion of the lower surface of the electronic component to prevent the warpage from being generated at the electronic component.

In some example embodiments, each of the patches 160 may be positioned at a central portion between adjacent four second lower pads 150. In some example embodiments, each of the patches 160 may be included in a body central position inside of a virtual quadrangle formed by the four second lower pads 150. For example, gaps between the patch 160 and the adjacent four second lower pads 150 may be same. Alternatively, the gaps between the patch 160 and the adjacent four second lower pads 160 may be different from each other.

The patches 160 may include an insulation material. For example, the patches 160 may include a solder resist, but are not limited thereto.

In some example embodiments, each of the patches 160 may have a cylindrical shape. Thus, each of the patches 160 may have a circular upper surface. The circular upper surface of the patch 160 may be configured to make contact with the central portion of the lower surface of the electronic component.

In some example embodiments, each of the patches 160 may have a diameter of about 50 micrometers (μm) to about 70 μm. Each of the patches 160 may have a thickness (e.g., in a vertical direction) of about 35 μm to about 38 μm. However, the diameter and the thickness of the patch 160 are not restricted to a specific range.

The first dam 170 may be arranged on edge portion of the second region R2. In some example embodiments, the first dam 170 may include a pair of dams arranged along the first direction D1 among the edge portions of the second region R2. The first dam 170 may support first edge portions of the lower surface of the electronic component along the first direction D1 and may auxiliarily suppress the warpage of the electronic component along the second direction D2. The first dam 170 may have a thickness substantially the same as the thickness of the patch 160.

In some example embodiments, the first dam 170 may include an insulation material. For example, the first dam 170 may include a material substantially the same as the material of the patch 160 (e.g., the solder resist) but is not limited thereto.

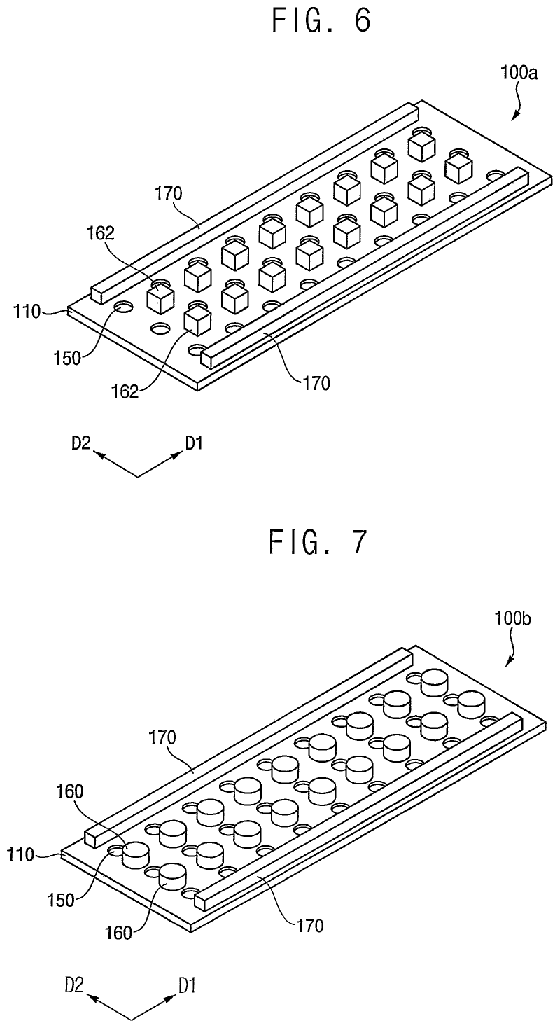

FIG. 6 is a perspective view illustrating a package substrate in accordance with some example embodiments.

A package substrate 100a may include elements substantially the same as those of the package substrate 100 in FIG. 4 except for a shape of a patch. Thus, the same reference numerals may refer to the same elements and any further illustrations with respect to the same elements may be omitted herein for brevity.

Referring to FIG. 6, each of the patches 162 may have a rectangular parallelepiped shape. Thus, each of the patches 162 may have a rectangular upper surface. The rectangular upper surface of the patch 162 may make contact with the central portion of the lower surface of the electronic component.

FIG. 7 is a perspective view illustrating a package substrate in accordance with some example embodiments.

A package substrate 100b may include elements substantially the same as those of the package substrate 100 in FIG. 4 except for a position of a patch. Thus, the same reference numerals may refer to the same elements and any further illustrations with respect to the same elements may be omitted herein for brevity.

Referring to FIG. 7, each of the patches 160 (and/or, though not illustrated, patches 162) may be positioned between the adjacent two second lower pads 150 along the second direction D2. For example, the patch 160 may be arranged at a central portion between the adjacent two second lower pads 150 along the second direction D2. Thus, gaps between the patch 160 and the adjacent two second lower pads 150 along the second direction D2 may be same. Alternatively, the gaps between the patch 160 and the adjacent two second lower pads 150 along the second direction D2 may be different from each other.

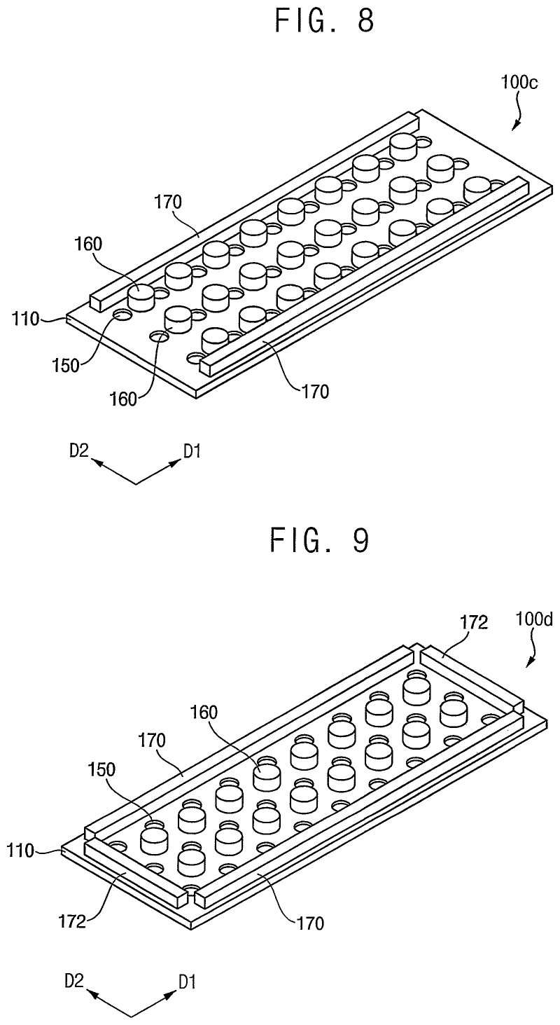

FIG. 8 is a perspective view illustrating a package substrate in accordance with some example embodiments.

A package substrate 100c of example embodiments may include elements substantially the same as those of the package substrate 100 in FIG. 4 and/or the package substrate 100b in FIG. 7, except for a position of a patch. Thus, the same reference numerals may refer to the same elements and any further illustrations with respect to the same elements may be omitted herein for brevity.

Referring to FIG. 8, each of the patches 160 (and/or, though not illustrated patches 162) may be positioned between the adjacent two second lower pads 150 along the first direction D1. For example, the patch 160 may be arranged at a central portion between the adjacent two second lower pads 150 along the first direction D1. Thus, gaps between the patch 160 and the adjacent two second lower pads 150 along the first direction D1 may be same. Alternatively, the gaps between the patch 160 and the adjacent two second lower pads 150 along the first direction D1 may be different from each other.

FIG. 9 is a perspective view illustrating a package substrate in accordance with example embodiments.

A package substrate 100d of example embodiments may include elements substantially the same as those of the package substrate 100 in FIG. 4 except for further including a second dam. Though not illustrated, the inclusion of the further second dam may also be included in, e.g., the semiconductor substrate 100a, 100b, 100c, and/or 100d. Thus, the same reference numerals may refer to the same elements and any further illustrations with respect to the same elements may be omitted herein for brevity.

Referring to FIG. 9, the package substrate 100d may further include a second dam 172. The second dam 172 may include a pair of dams arranged along the second direction D2 among the edge portions of the second region R2. The second dam 172 may support second edge portions of the lower surface of the electronic component along the second direction D2 to auxiliarily suppress the warpage of the electronic component along the first direction D1. Thus, the second dam 172 may have a thickness substantially the same as the thickness of the patch 160.

In example embodiments, the second dam 172 may include an insulation material. For example, the second dam 172 may include a material substantially the same as the material of the patch 160 (e.g., the solder resist), but is not limited thereto.

Further, the second dam 172 may have both ends spaced apart from both ends of the first dam 170. Alternatively, both ends of the second dam 172 may be connected to both ends of the first dam 170. In these cases, one dam having a rectangular frame shape may be configured to surround the second region R2.

Alternatively, the package substrate 100d may include only the second dam 172, (e.g., not include the first dam 170).

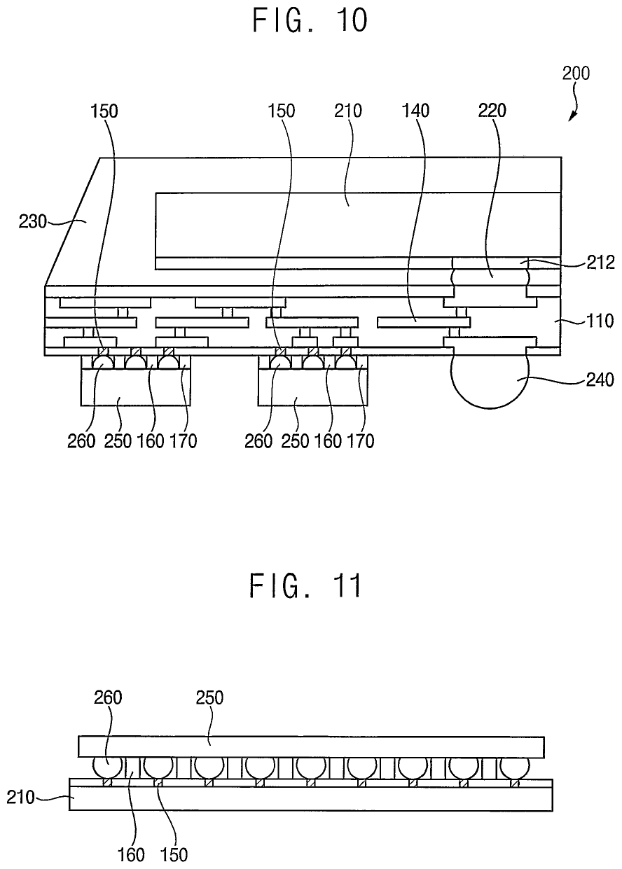

FIG. 10 is a cross-sectional view illustrating a semiconductor package including the package substrate in FIG. 2 and FIG. 11 is an enlarged cross-sectional view illustrating an electronic component mounted on a lower surface of the package substrate in FIG. 10.

Referring to FIGS. 10 and 11, a semiconductor package 200 may include a package substrate 100, a semiconductor chip 210, a molding member 230, external terminals 240 and an electronic component 250.

The package substrate 100 may have the structure of the package substrate 100 in FIG. 2, the package substrate 100a in FIG. 6, the package substrate 100b in FIG. 7, the package substrate 100c in FIG. 8 and/or the package substrate 100d in FIG. 9. Thus, any further illustrations with respect to the package substrate 100 may be omitted herein for brevity.

The semiconductor chip 210 may be arranged on an upper surface of the package substrate 100. The semiconductor chip 210 may include a pad 212. The pad 212 may be arranged on a lower surface of the semiconductor chip 210. Thus, the lower surface of the semiconductor chip 210 may correspond to an active face of the semiconductor chip 210. The pad 212 may be connected with the upper pad 120 on the upper surface of the package substrate 100 via a conductive bump 220.

The molding member 230 may be formed on the upper surface of the package substrate 100 to cover the semiconductor chip 210. The molding member 230 may include an insulating material (e.g., such as an epoxy molding compound (EMC) and/or the like, but is not limited thereto).

The external terminals 240 may be mounted on the first lower pads 130 in the first region R1 of the lower surface of the package substrate 100. The external terminals 240 may include a conductive material and/or structure (e.g., solder balls, but the example embodiments are not limited thereto).

The electronic component 250 may be mounted on the second lower pads 150 in the second region R2 of the lower surface of the package substrate 100. Particularly, the electronic component 250 may be mounted on the second lower pads 150 via conductive bumps 260. As mentioned above, the electronic component 250 may be mounted on the second lower pads 150 using the nozzle. Thus, a warpage may be generated at the electronic component by the load applied to the electronic component 250 from the nozzle.

As mentioned above, the upper surfaces of the patches 160 may make contact with the central portion of the lower surface of the electronic component 250 to support the electronic component 250. Thus, the warpage may be prevented and/or mitigated at the electronic component. Further, the first dam 170 may support the edge portion of the lower surface of the electronic component 250 to auxiliarily suppress the warpage of the electronic component 250 from being generated.

In some example embodiments, each of the patches 160 may have the thickness of no more than a thickness of the conductive bump 260. For example, the thickness of the patch 160 may be substantially the same (e.g., within manufacturing tolerances) as the thickness of the conductive bump 260. When the thickness of the patch 160 may be thicker than the thickness of the conductive bump 260, the conductive bump 260 may not make contact with the second lower pad 150. Thus, the contact between the conductive bump 260 and the second lower pad 150 may be secured by restricting the thickness of the patch 160 of no more than the thickness of the conductive bump 260.

In some example embodiments, the electronic component 250 may include the passive element, not is limited thereto. The passive element may store, dissipate, and/or release power (and/or energy) and may include, e.g., a capacitor (such as a multi-layer ceramic capacitor (MLCC), a low inductance chip capacitor (LICC), a silicon capacitor, etc.), an inductor (such as a power inductor, etc.), a resistor, but the example embodiments are not limited thereto.

According to example embodiments, the patches may be arranged between the second lower pads in the second region of the lower surface of the package substrate to prevent the warpage of the electronic component on the second lower pads from being generated. Further, the dam may be arranged on the edge portions of the second region to auxiliarily suppress the warpage of the electronic component. As a result, the potential for a crack forming in the electronic component may be eliminated and/or reduced.

The foregoing is illustrative of some example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A package substrate comprising:
an insulation substrate including a first region and a second region on a lower surface of the insulating substrate;
a plurality of upper pads on an upper surface of the insulation substrate;
a plurality of first lower pads in the first region, the plurality of first lower pads configured to mount external terminals;
a plurality of second lower pads in the second region, the plurality of second lower pads configured to mount an electronic component;
a plurality of patches between the second lower pads in the second region, the plurality of patches configured to suppress warpage of the electronic component; and
at least one dam extending along an edge portion of the second region, the at least one dam configured to auxiliarily suppress warpage of the electronic component,
wherein each of the patches has a diameter of 50 μm to 70 μm and a thickness of 35 μm to 38 μm.

2. The package substrate of claim 1, wherein the plurality of second lower pads are uniformly arranged in a first direction and a second direction substantially perpendicular to the first direction.

3. The package substrate of claim 2, wherein each of the plurality of patches is between two adjacent ones of the plurality of second lower pads.

4. The package substrate of claim 2, wherein each of the plurality of patches is at a central portion between four adjacent second lower pads.

5. The package substrate of claim 1, wherein the plurality of patches comprise an insulation material.

6. The package substrate of claim 1, wherein each of the plurality of patches has at least one of a cylindrical shape or a rectangular parallelepiped shape.

7. The package substrate of claim 1, wherein the plurality of patches have a thickness substantially the same as a thickness of the at least one dam.

8. The package substrate of claim 1, wherein the at least one dam comprises:
a first dam extending in a first direction; and
a second dam extending in a second direction substantially perpendicular to the first direction.

9. The package substrate of claim 1, wherein the at least one dam comprises an insulation material.

10. A package substrate comprising:
an insulation substrate including a first region and a second region on a lower surface of the insulation substrate;
a plurality of upper pads on an upper surface of the insulation substrate;
a plurality of first lower pads in the first region, the plurality of first lower pads configured to mount external terminals;
a plurality of second lower pads arranged in the second region, the plurality of second lower pads configured to mount an electronic component; and
a plurality of patches between the second lower pads in the second region, the plurality of patches configured to suppress warpage of the electronic component.

11. The package substrate of claim 10, wherein the plurality of second lower pads are uniformly arranged in a first direction and a second direction substantially perpendicular to the first direction.

12. The package substrate of claim 11, wherein each of the plurality of patches is between two adjacent ones of the plurality of second lower pads.

13. The package substrate of claim 11, wherein each of the plurality of patches is at a central portion between four adjacent ones of the plurality of second lower pads.

14. The package substrate of claim 10, further comprising:
at least one dam extending along an edge portion of the second region, the at least one dam configured to auxiliarily suppress the warpage of the electronic component,

15. The package substrate of claim 14, wherein the at least one dam comprises:
a first dam extending in a first direction; and
a second dam extending in a second direction substantially perpendicular to the first direction.

16. A semiconductor package comprising:
a package substrate including
an insulation substrate including a first region and a second region on a lower surface of the insulation substrate,
a plurality of upper pads on an upper surface of the insulation substrate,
a plurality of first lower pads in the first region,
a plurality of second lower pads in the second region, and
a plurality of patches between the second lower pads in the second region and configured to suppress warpage of an electronic component;
a semiconductor chip mounted on the upper pads;
a plurality of external terminals mounted on the first lower pads; and
the electronic component mounted on the second lower pads.

17. The semiconductor package of claim 16, further comprising:
a plurality of conductive bumps interposed between the electronic component and the plurality of second lower pads.

18. The semiconductor package of claim 17, wherein the plurality of patches has a thickness of no more than a thickness of each of the conductive bumps.

19. The semiconductor package of claim 16, wherein the package substrate further comprises at least one dam extending along an edge portion of the second region of the insulation substrate, the at least one dam configured to auxiliarily suppress the warpage of the electronic component.

20. The semiconductor package of claim 19, wherein the at least one dam comprises:
a first dam extending in a first direction; and
a second dam extending in a second direction substantially perpendicular to the first direction.
